(19) United States
(12) Patent Application Publication
(10) Pub. No.: US 2013/0103328 A1
(43) Pub. Date: Apr. 25, 2013

(54) SCREENING DEVICE FOR SEMICONDUCTOR DEVICES, SCREENING METHOD FOR SEMICONDUCTOR DEVICES AND PROGRAM THEREOF

(71) Applicant: RENESAS ELECTRONICS CORPORATION, Kawasaki-shi (JP)

(72) Inventor: Kazuhiro SAKAGUCHI, Kanagawa (JP)

(73) Assignee: RENESAS ELECTRONICS CORPORATION, Kawasaki-shi (JP)

(21) Appl. No.: 13/649,643

(22) Filed: Oct. 11, 2012

(30) Foreign Application Priority Data
Oct. 19, 2011 (JP) 2011-229728

(51) Int. Cl. G06F 19/00; G01R 31/26

(52) U.S. Cl. 702/58

(57) ABSTRACT

A screening device for semiconductor devices includes a data divider to generate measurement value subsets by sub-grouping a measurement value set including measurement results relating to characteristics of the semiconductor device based on a specific standard; a first evaluation value calculator to calculate a first evaluation value that is an evaluation standard for measurement results included in the plural respective measurement value subsets; a data converter to convert measurement results contained in the plural respective measurement value subsets based on the first evaluation value; a second evaluation value calculator to calculate a second evaluation value that is an evaluation standard for measurement results after conversion by the data converter; and a decision unit to decide if the semiconductor device under measurement is a pass or fail based on the second evaluation value.

### CROSS-REFERENCE TO RELATED APPLICATIONS

The disclosure of Japanese Patent Application No. 2011-229728 filed on Oct. 19, 2011 including the specification, drawings and abstract is incorporated herein by reference in its entirety.

### BACKGROUND

The present invention relates to a screening device for semiconductor devices, a screening method for semiconductor devices, and a program. The present invention relates in particular to a screening device for semiconductor devices, a screening method for semiconductor devices, and a program that are based on measurement results relating to the characteristics of the semiconductor device.

In the process of manufacturing a semiconductor device, various tests are performed on the semiconductor device that was manufactured. Implementing these tests ensures the quality of the semiconductor device.

Here, Japanese Unexamined Patent Application Publication No. 2008-002900 discloses a screening device that measures physical quantities such as the electrical current values or voltage values during testing of the semiconductor devices and analyzes the distribution of the measured physical quantities. The Japanese Unexamined Patent Application Publication No. 2008-002900 stores the position over the wafer of the semiconductor device for measurement along with the physical quantities as a data file. After the testing is completed, the screening device analyzes the distribution of the physical quantities stored in the data file and identifies those semiconductor devices indicating physical quantities in the test results that deviate from pre-established judgment criterion. The specified semiconductor device is in this way screened for causes of latent defects.

### SUMMARY

The above disclosed documents of the related art are repeatedly referred to in this text. The following analysis was rendered from the viewpoint of the present invention.

FIG. 2 is a flat view showing an example of the plural semiconductor devices produced in the wafer. Plural semiconductor devices may in some cases be measured simultaneously during measurement of the characteristics of the semiconductor device shown in FIG. 2. Simultaneously measuring a plurality of semiconductor devices allows shortening the testing time. In FIG. 2, the characteristics of the four semiconductor devices D01 to D04 shown by the oblique lines are measured simultaneously. This type of method for measuring the characteristics is called multiple item measurement and is described next.

FIG. 3 is a drawing showing an example of the coupling structure for the semiconductor device and tester during the multiple item measurement. In FIG. 3, each of the measurement units TU01 to TU04 measures the characteristics of the semiconductor devices D01 to D04. Tiny differences in characteristics possessed by each of the measurement units TU01 to TU04 and differences in the characteristics of the circuits coupling each measurement unit to each semiconductor device might sometimes affect the measurement results. The measurement results will therefore never attain a complete match with each other, even assuming that the measurement units TU01 to TU04 are measuring semiconductor devices having identical characteristics. So histogram measurement values acquired from the individual measurement units TU01 to TU04 will each have separate distributions.

FIG. 4 is a graph showing an example of histogram measurement values. Simultaneously measuring characteristics of plural semiconductor devices by using different measurement units as shown in FIG. 4 will cause separated distributions from each measurement unit on the histogram due to the above described differences in characteristics.

The screening device disclosed in Japanese Unexamined Patent Application Publication No. 2008-002900 can sort out or eliminate those semiconductor devices possessing latent causes of defects based on physical quantities of semiconductor devices in the wafer. A precondition for results from measuring semiconductor device physical quantities is that the semiconductor devices possess one main distribution.

FIG. 5 is a graph showing an example of a histogram for measurement values. As can be seen in FIG. 5, semiconductor devices showing a value larger (smaller) than a pre-established standard value are judged as defects. Semiconductor devices showing values smaller (larger) than a pre-established standard value are judged as good (non-defective) items, however distributions that are not within the main distribution of the measurement value are seen as deviating distributions and screened out due to possessing inherent latent defects. Here a deviating distribution is judged by the extent of separation from the center (average value) of the main distribution. However, as already described, histograms of measurement values are not limited to shapes possessing only one main distribution as shown in FIG. 5.

FIG. 6 is a graph showing one example of a histogram for measurement values. FIG. 6 shows a histogram of measurement values for the case of two measurement units. A distribution 1 and a deviating distribution 1 are histograms measurement values from one measurement unit; and a distribution 2 is a histogram of measurement values from another measurement unit. These distributions are within the range of pre-established standard values not shown in the drawing and all the semiconductor devices are judged as good (non-defective) items. If the distribution 1 and distribution 2 are considered as one main distribution, then the deviating distribution 1 between the distribution 1 and distribution 2 is also considered a normal distribution. The reason is that the deviating distribution 1 is embedded between the distribution 1 and distribution 2 and therefore appears as a normal distribution. The judgment method disclosed in Japanese Unexamined Patent Application Publication No. 2008-002900 is therefore incapable of accurately identifying this type of deviating distribution 1 as a deviating distribution.

However, the measurement unit that acquired measurement values contained in distribution 1, and the measurement unit that acquired measurement values contained in distribution 2 are different from each other so a semiconductor device whose measurement values match the deviating distribution 1 should be judged as a defect item (semiconductor device having causes of latent defects) for screening. Identifying a semiconductor device whose measurement values show inclusion within a deviating distribution embedded between the main distributions is therefore impossible in histograms having two or more main distributions. A screening device for semiconductor devices is therefore needed that is capable of identifying semiconductor devices having singular values that deviate from the main distribution even when there are multiple distributions in measurement value histograms.

A screening device for semiconductor devices according to a first aspect of the present invention includes a data divider to generate plural measurement value subsets by dividing a measurement value set including measurement results relating to characteristics of semiconductor devices based on a specific standard; a first evaluation value calculator to calculate a first evaluation value that serves as an evaluation standard for measurement results included in the plural respective measurement value subsets; a data converter to convert measurement results contained in the plural respective measurement value subsets based on the first evaluation value; a second evaluation value calculator to calculate a second evaluation value that serves as an evaluation standard for measurement results after conversion by the data converter; and a decision unit to decide if the semiconductor device under measurement is a pass or fail based on the second evaluation value.

A screening method for semiconductor devices according to a second aspect of the present invention includes the steps of: dividing the data to generate plural measurement value subsets by sub-grouping a measurement value set including measurement results relating to characteristics of semiconductor devices based on a specific standard; calculating a first evaluation value serving as an evaluation standard for measurement results included in the plural respective measurement value subsets; converting measurement results contained in the plural respective measurement value subsets based on the first evaluation value; calculating a second evaluation value that serves as an evaluation standard for measurement results after conversion in the data conversion step; and deciding whether to pass or fail the semiconductor device under measurement based on the second evaluation value.

A program to operate a computer as a screening device for semiconductor devices according to a third aspect of the present invention by executing on a computer the processes of: dividing the data to generate plural measurement values subsets by sub-grouping a measurement value set including measurement results relating to characteristics of semiconductor devices based on a specific standard; calculating a first evaluation value serving as an evaluation standard for measurement results included in the plural respective measurement value subsets; converting measurement results contained in the plural respective measurement value subsets based on the first evaluation value; calculating a second evaluation value serving as an evaluation standard for measurement results after conversion by the data converter; and deciding whether to pass or fail the semiconductor device under measurement based on the second evaluation value. This program can be recorded on a storage medium capable of being loaded onto a computer. The present invention can in other words be achieved as a computer program product. The storage medium may be implemented as a non-transient medium.

The aspects of the present invention respectively provide a screening device for semiconductor devices, a screening method for semiconductor devices, and a program capable of identifying semiconductor devices having singular values that deviate from the main distribution even when there are multiple distributions in measurement value histograms.

### BRIEF DESCRIPTION OF THE DRAWINGS

FIG. 1 is a drawing for describing an overview of a first embodiment of the present invention;

FIG. 2 is a flat view showing one example of the semiconductor device produced in the wafer;

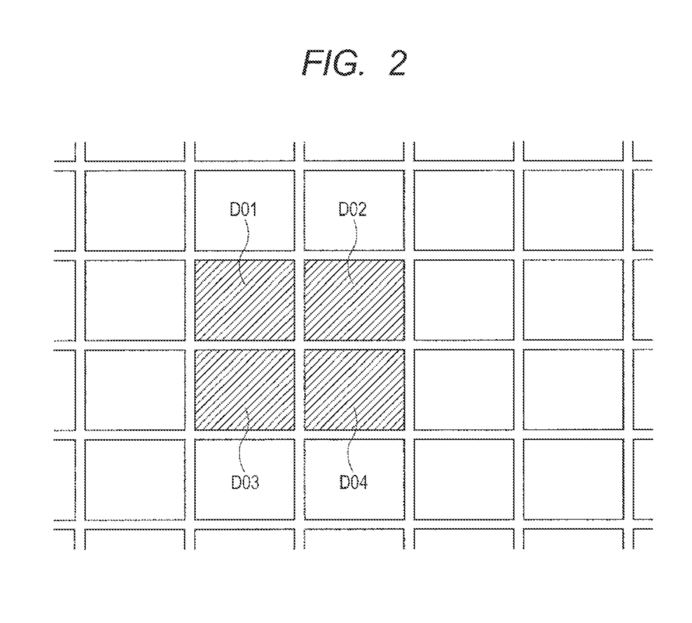

FIG. 3 is a drawing showing one example of the structure for coupling the semiconductor device to the tester during multiple item measurement;

FIG. 4 is a graph showing an example of a histogram for measurement values;

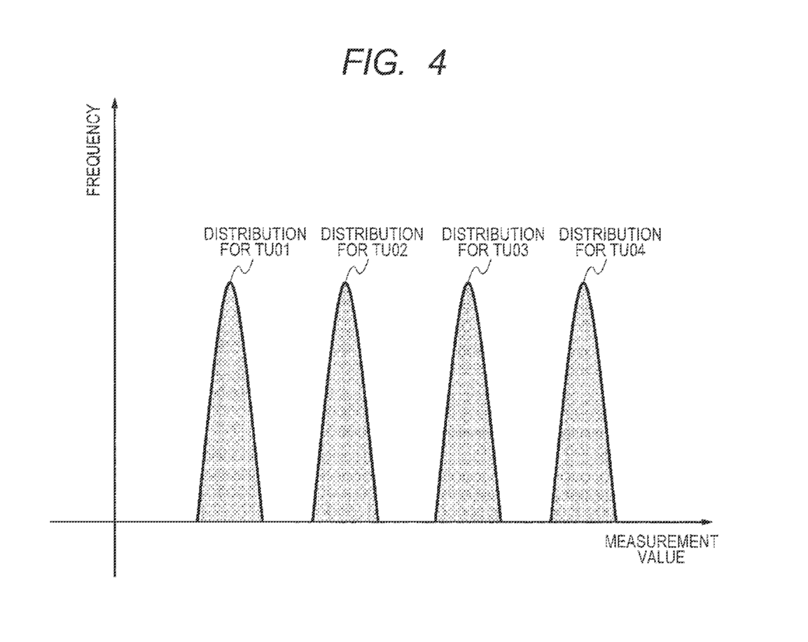

FIG. 5 is a graph showing an example of a histogram for measurement values;

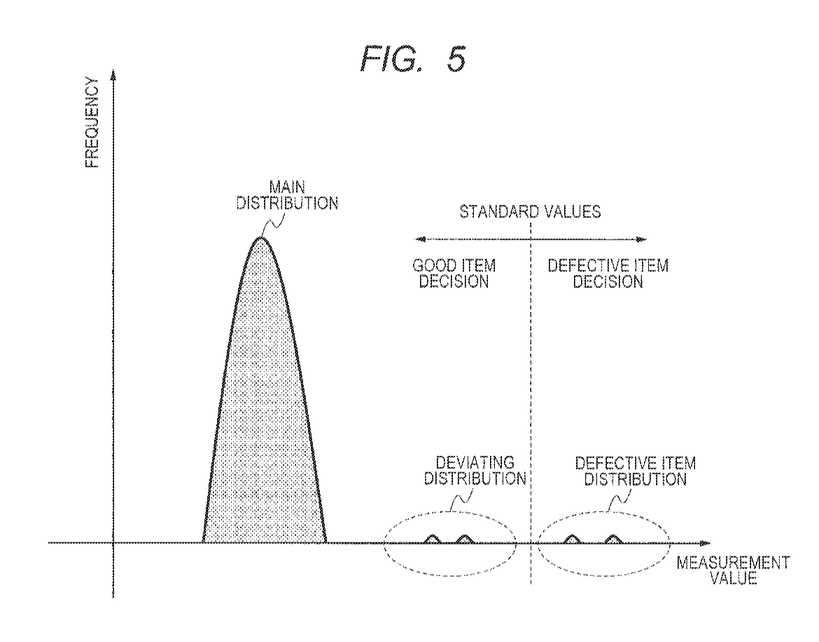

FIG. 6 is a graph showing an example of a histogram for measurement values;

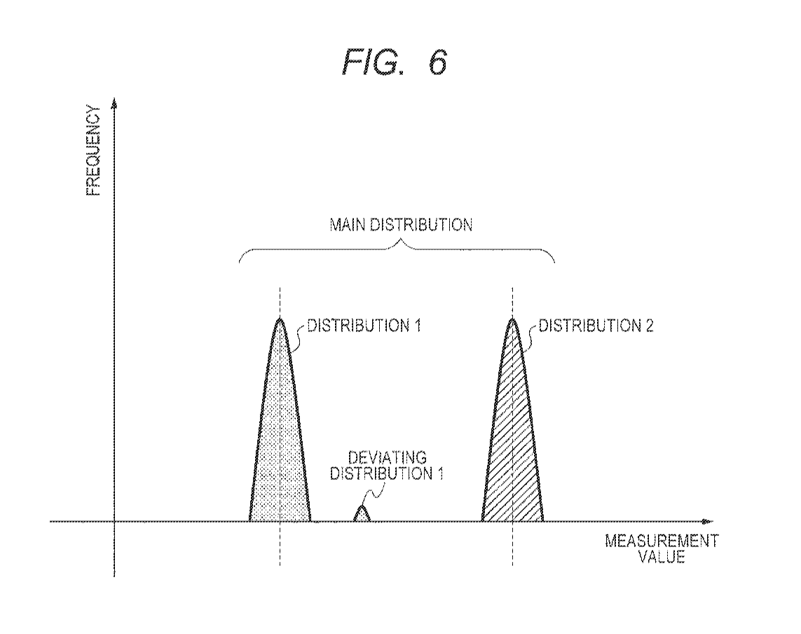

FIG. 7 is a drawing showing one example of the structure of a screening device of the first embodiment of the present invention;

FIG. 8 is drawing showing one example of the internal structure of a calculator shown in FIG. 7;

FIG. 9 is a flow chart for showing one example of the operation of the screening device of the first embodiment of the present invention;

FIG. 10 is a drawing showing an example of the division of the set A;

FIG. 11 is a drawing showing one example of a histogram of measurement values prior to data conversion;

FIG. 12 is a drawing showing one example of a histogram of measurement values after data conversion;

FIG. 13 is a diagram showing an example of the internal structure of the calculator contained in a screening device of a second embodiment of the present invention;

FIG. 14 is a flow chart showing an example of the operation of the screening device of the second embodiment of the present invention;

FIG. 15 is a drawing showing an example of a histogram for measurement value prior to data conversion;

FIG. 16 is a drawing showing an example of a histogram for measurement values after data conversion; and

FIG. 17 is a drawing showing an example of a measurement value histogram.

### DETAILED DESCRIPTION

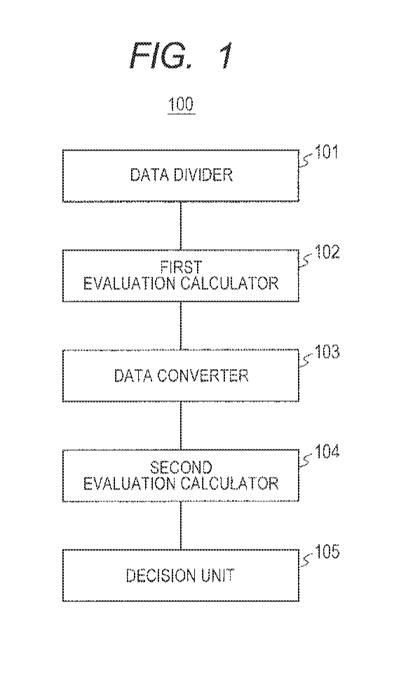

An overview of the first embodiment is first of all described while referring to FIG. 1. The drawing reference numerals assigned to this overview are attached to the structural elements for purposes of convenience as examples to assist in understanding and are not intended to limit the present invention to the examples shown in the drawings.

As already described, identifying semiconductor devices that exhibit measurement values within the deviating distribution embedded between the main distributions is impossible in a histogram possessing two or more main distributions. A screening device for semiconductor devices is therefore needed that is capable of identifying those semiconductor devices showing singular values deviating from the main distribution in measurement value histograms even when there are plural main distributions.

One example of such a screening device 100 for semiconductor devices is therefore shown in FIG. 1. The screening device 100 for semiconductor devices shown in FIG. 1 is comprised of a data divider 101 to generate plural measurement values subsets by sub-grouping a measurement value set including measurement results relating to characteristics of semiconductor devices based on a specific standard; a first evaluation value calculator 102 to calculate a first evaluation value that serves as an evaluation standard for measurement results included in the plural respective measurement value subsets; a data converter 103 to convert measurement results contained in the plural respective measurement value subsets based on the first evaluation value; a second evaluation value calculator 104 to calculate a second evaluation value that serves as an evaluation standard for measurement results after conversion by the data converter; and a decision unit 105 to decide if the semiconductor device under measurement is a pass or fail based on the second evaluation value.

The semiconductor device measurement results obtained from the tester unit include measurement results from semiconductor devices contained in the plural wafers and measurement results measured by plural measurement units. The data divider 101 sub-groups the measurement value sets configured from these measurement results. More specifically, the data divider may sub-group the measurement value sets by wafers or by individual measurement units. The first evaluation value calculator 102 then calculates evaluation values (first evaluation value) for measurement values included in the measurement value subsets made by sub-grouping measurement value sets. The data converter 103 converts measurement values contained in the measurement value subsets based on the first evaluation value. The conversion is at this time made so that evaluation standards for semiconductor device pass-fail decisions are standardized by utilizing evaluation values (second evaluation value) calculated by the second evaluation value calculator 104. More specifically, conversion is implemented so as to match the average values contained in the respective measurement value subsets by employing the standard deviation and average values for measurement values contained in the measurement value subsets as the second evaluation value. As a result of this conversion, the respective distributions in the measurement value subsets match with no separation, so a screening device for semiconductor devices is in this way provided that is capable of identifying semiconductor devices exhibiting singular values deviating from the main distribution.

The present invention is capable of achieving the following modes.

[Mode 1] A screening device for semiconductor devices as described in the first aspect.

[Mode 2] The data dividers preferably include a first data divider to sub-group the measurement value sets by each wafer including the semiconductor device for measurement; and as second data divider to sub-group the measurement value subsets after sub-grouping by the first data divider by each measurement unit measuring the semiconductor device

[Mode 3] The first evaluation value calculator preferably calculates the average value of the measurement results contained in each of the plural measurement value subsets as a first evaluation value.

[Mode 4] The data converter preferably calculates a first conversion coefficient for each of the plural measurement value subsets that serves as a conversion coefficient to add to each average value calculated by the first evaluation value calculator and matches each average value calculated by the first evaluation value calculator, and performs a first conversion by adding a first conversion coefficient to the measurement results contained in each of the plural measurement value subsets.

[Mode 5] The first evaluation value calculator preferably also calculates a standard deviation for measurement results contained in each of the plural measurement value subsets as a first evaluation value; and as a conversion coefficient to multiply by the standard deviation calculated by the first evaluation value calculator, the data converter preferably calculates a second conversion coefficient matching each of the standard deviations calculated by the first evaluation value calculator for each of the plural measurement value subsets, and performs a second conversion by multiplying the second conversion coefficient by the measurement results after the first conversion.

[Mode 6] The second evaluation value calculator preferably calculates an average value and standard deviation for measurement results contained in each of the plural measurement value subsets that were converted by the data converter to serve as a second evaluation value.

[Mode 7] The decision unit preferably judges the semiconductor device for measurement as a pass-fail based on the average value and standard deviation calculated by the second evaluation value calculator, and pre-established standards information.

[Mode 8] A screening method for semiconductor devices as described in the second aspect.

[Mode 9] A first evaluation value calculation process preferably includes a process for calculating an average value for measurement results contained in each of the plural measurement value subsets as a first evaluation value; a data conversion process preferably includes a process to calculate a first conversion coefficient for adding to the average value calculated in the first evaluation calculation process, and for matching the respective average values calculated in the first evaluation value calculation process for each of the plural measurement value subsets; and a first conversion process to add the first conversion coefficient to the measurement results contained in each of the plural measurement value subsets.

[Mode 10] The first evaluation value calculation process preferably further includes a process for calculating a standard deviation for measurement results contained in each of the plural measurement value subsets as a first evaluation value; the data conversion process preferably includes a process to calculate a second conversion coefficient to multiply by the standard deviation calculated in the first evaluation value calculation process, and for matching the respective standard deviations calculated in the first evaluation value calculation process to each of the plural measurement value subsets; and a second conversion process to multiply the second conversion coefficient by the measurement results after the first conversion process.

[Mode 11] A program as described in the third aspect.

[Mode 12] The first evaluation value calculation process preferably executes a process to calculate an average value for the measurement results contained in each of the plural measurement value subsets as a first evaluation value; the data conversion process preferably includes a process to calculate a first conversion coefficient to add to the average value calculated in the first evaluation value calculation process, and for matching the respective average values calculated in the first evaluation value calculation process for each of the plural measurement value subsets; and preferably executes a first conversion process to add a first conversion coefficient to the measurement results contained in each of the plural measurement value subsets.

[Mode 13] The first evaluation value calculation process further preferably executes a process to calculate a standard deviation for the measurement results contained in each of the plural measurement value subsets as a first evaluation value; and the data conversion process preferably executes a process to calculate a second conversion coefficient to multiply by the standard deviation calculated in the first evaluation value calculation process, and for matching the respective standard deviations calculated in the first evaluation value calculation process in each of the plural measurement value subsets, and preferably executes a second conversion process to multiply the second conversion coefficient by the measurement results after the first conversion process.

The specific embodiments are described next in detail while referring to the drawings.

### First Embodiment

The first embodiment of the present invention is described next in detail while referring to the drawings.

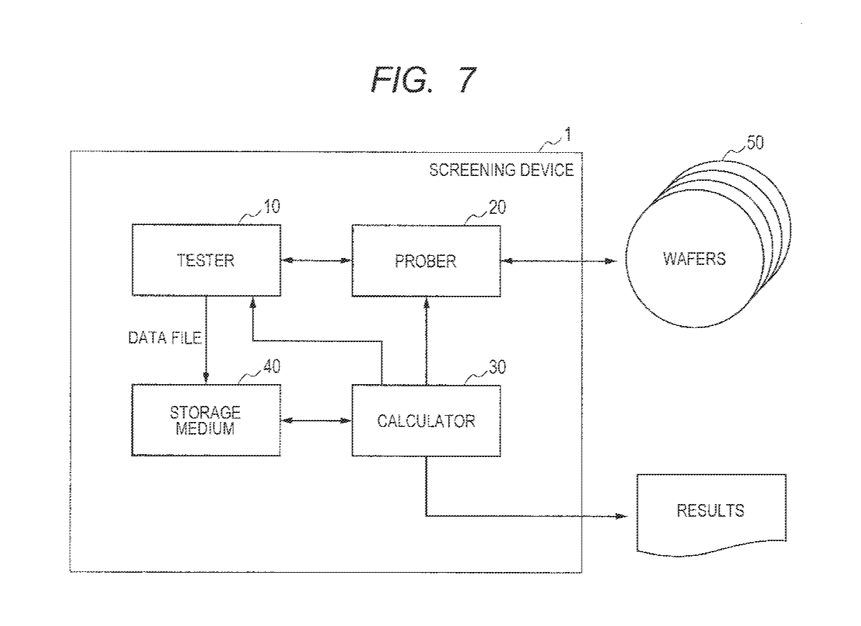

FIG. 7 is a drawing showing one example of the structure of the screening device 1 of the first embodiment.

The screening device 1 is comprised of a tester 10, a prober 20, a calculator 30, and a storage medium 40. The screening device 1 measures the characteristics of the semiconductor device contained in a wafer 50 and identifies semiconductor devices judged as possessing inherent latent causes of defects. The specified results are output to an external section.

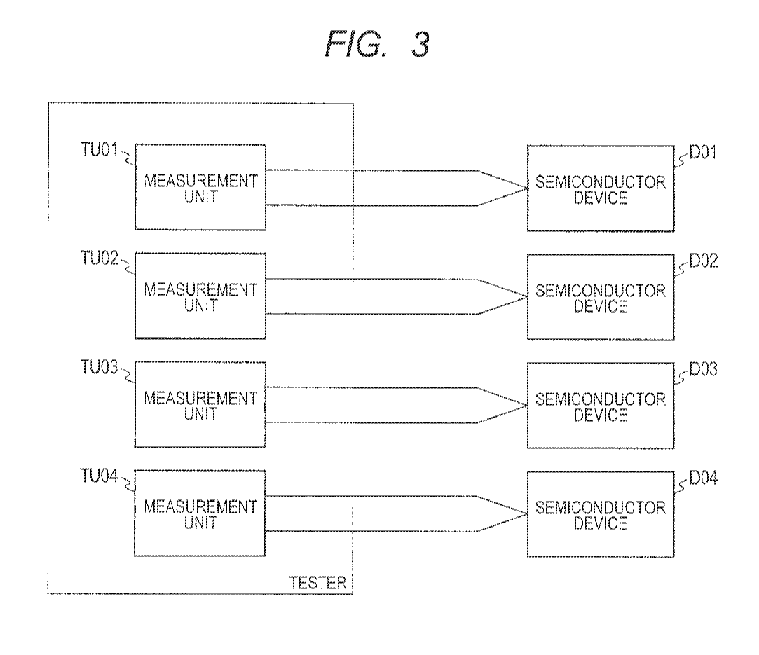

The tester 10 is electrically coupled by way of a prober 20 to the semiconductor device contained in the wafer 50. The tester 10 operates based on instructions issued from the calculator 30. The tester 10 is further coupled to the storage medium 40. The tester 10 stores the position information of the semiconductor devices contained in the wafer 50 (position information in the wafer 50) as well as measurement values relating to the semiconductor device characteristics in data files. The tester 10 includes plural measurement units as shown in FIG. 3.

The prober 20 transmits the position information for the semiconductor device in the wafer 50 to the tester 10.

The calculator 30 is coupled to the tester 10, the prober 20 and the storage medium 40. The calculator 30 controls the tester 10 and the prober 20 by loading and executing the program stored on the storage medium 40. The calculator 30 is further capable of accessing data files stored in the storage medium 40 and can analyze the measurement values relating to semiconductor device characteristics stored in the data files.

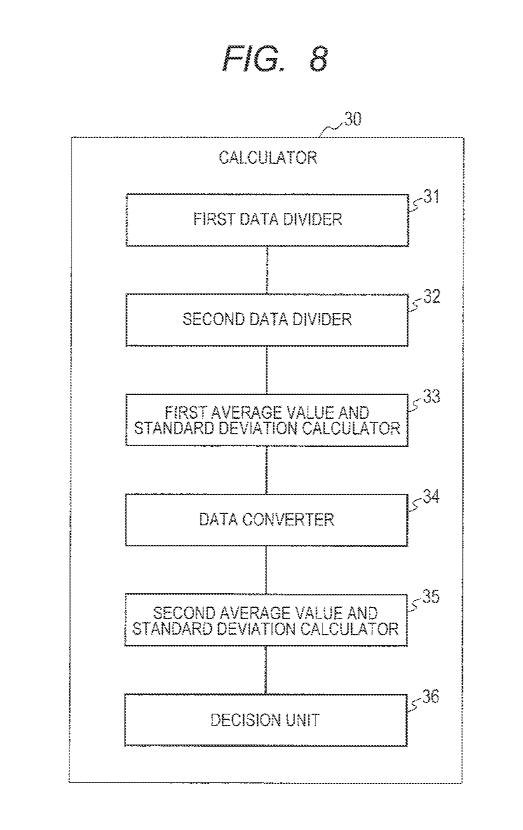

FIG. 8 is a drawing showing an example of the internal structure of the calculator 30.

The calculator 30 is comprised of at least a first data divider 31, a second data divider 32, a first average value and standard deviation calculator 33, a data converter 34, a second average value and standard deviation calculator 35, and a decision unit 36.

The first data divider 31 sub-groups the information (semiconductor device measurement value information) loaded from the data file by the specified method.

The second data divider 32 is coupled to the first data divider 31. The second data divider 32 utilizes a specified method to sub-group the measurement value information that was sub-grouped by the first data divider 31. The method for sub-grouping implemented by the first data divider 31 and the second data divider 32 is described later.

The first average value and standard deviation calculator 33 is coupled to the second data divider 32. The first average value and standard deviation calculator 33 calculates an average value and standard deviation value for the measurement values contained in the subsets generated by the sub-grouping performed by the second data divider 32. The first average value and standard deviation calculator 33 is equivalent to the above described first evaluation value calculator.

The data converter 34 is coupled to the first average value and standard deviation calculator 33. The data converter 34 converts the measurement value data conversion based on the average value calculated by the first average value and standard deviation calculator 33.

The second average value and standard deviation calculator 35 is coupled to the data converter 34. The second average value and standard deviation calculator 35 calculates an average value and standard deviation for post-conversion measurement values for each subset generated by the sub-grouping performed by the second data divider 32. The second average value and standard deviation calculator 35 is equivalent to the above described second evaluation value calculator.

The decision unit 36 is coupled to the second average value and standard deviation calculator 35. The decision unit 36 identifies the semiconductor device possessing the latent defect cause based on the average value and standard deviation calculated by the second average value and standard deviation calculator 35 and the pre-established standard value, and outputs those results.

The operation of the screening device 1 is described next.

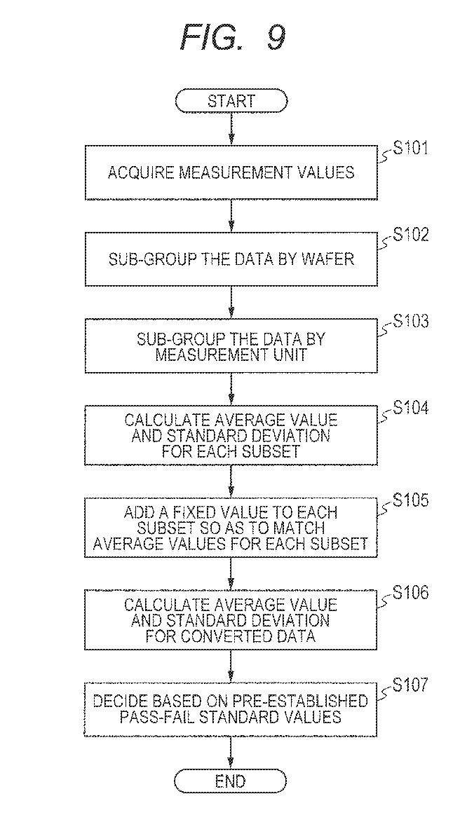

FIG. 9 is a flow chart showing an example of the operation of the screening device 1.

In step S101, the calculator 30 controls the tester 10 and the prober 20 and measures the characteristics of the semiconductor devices contained in the wafer 50.

The tester 10 that received instructions from the calculator 30 supplies a pre-designated power (quantity) to the semiconductor device contained in the wafer 50 by way of the prober 20. The tester 10 applies a pre-specified electrical signal to the semiconductor device and also acquires electrical current values and voltage values showing the semiconductor device characteristics. The wafer 50 in this case contains a plurality of semiconductor devices and the tester 10 simultaneously applies electrical signal to a pre-specified number of semiconductor devices and simultaneously acquires the respective semiconductor device characteristics (implements multiple item measurement).

The tester 10 stores the position information of the semiconductor device in the wafer 50, the semiconductor device measurement values (electrical current and voltage values, etc.), and information relating to the measurement units (measurement unit information) that measured the respective semiconductor devices into data files. In step S102, the calculator 30 accesses the storage medium 40 and loads the data file. The calculator 30 may be timed to load (read-out) the information stored in the data file after completing measurement of all semiconductor devices contained in the wafer 50 or after completing measurement of a portion of the semiconductor devices. The calculator 30 reads out the measurement value information and measurement unit information, and also the position information relating to the semiconductor device for measurement from the data files.

The set comprised of measurement value information loaded by the calculator 30 is here established as the set A. Namely, each element of the set A includes measurement value information relating to the semiconductor device for measurement. Semiconductor devices that match each of the elements in A are semiconductor devices judged as good (non-defective) item in the pre-established standard values.

In this step, the first data divider 31 also sub-groups the set A by a pre-established method. More specifically, the first data divider 31 sub-groups the set A so that measurement values acquired from the same wafer are grouped into the same set.

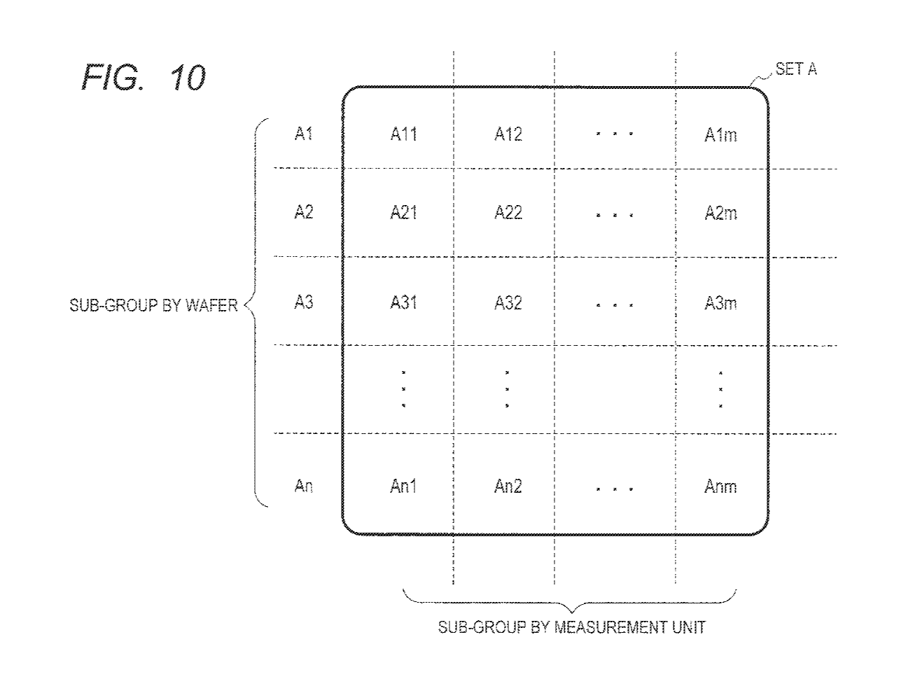

FIG. 10 is a drawing showing an example of sub-grouping the set A. The first data divider 31 sub-groups the set A into the groups A1, A2, . . . , An (n is an integer of 1 or more, and the same hereafter). The first data divider 31 at that time uses position information relating to the semiconductor device for measurement that was read out by the calculator 30. The first data divider 31 sub-groups the set A so that the measurement values acquired from the same wafer are in the same set and so the subsets A1 through An include only measurement values acquired from the same wafer.

In step S103, the second data divider 32 further sub-groups the subsets A1 to An grouped by wafer into measurement units. More specifically, measurement values from the same measurement unit are grouped into the same set. The subset A1 for example is sub-divided into A11, A12, . . . , A1m (m is an integer of 2 or more, and the same hereafter). The second data divider 32 in this case utilizes measurement unit information read out by the calculator 30. The first data divider 31 and the second data divider 32 sub-group the set A as shown in FIG. 10. The set A is in other words sub-grouped into A11, A12, . . . , A1m, A21, . . . , A2m, . . . , Anm.

In step S104, the first average value and standard deviation calculator 33 calculates the average value and standard deviation for measurement values included in the subsets A11 to Anm. Among measurement values contained in the subset Aij (i is an integer of 1 or more and n or less, j is an integer of 1 or more and m or less, and both i and j are the same hereafter) the average value is labeled AVEij, and the standard deviation is labeled SDij.

In this step, the average value AVE11 to AVEnm and the standard deviations SD11 to SDnm are calculated for each subset A11 to Anm obtained by the subgrouping by the first data divider 31 and the subgrouping by the second data divider 32.

In step S105, the data converter 34 converts data by fixed value addition on each measurement value contained in the subsets A1 to Anm. Here, a fixed value applied by the data converter 34 corresponds to the subsets A11 to Anm and the labels D11 to Dnm are attached. The fixed values D11 to Dnm are decided by implementing the following formula (1).

AVE11+D11=AVE12+D12=. . . =AVE1m+D1m=AVE1AVE21+D21=AVE22+D22=. . . =AVE2m+D2m=AVE2·AVEn1+Dn1=AVEn2+Dn2=. . . =AVEnm+Dnm=AVEn (1).

Namely, the data converter performs data conversion by adding Dij to measurement values for each element contained in the subset Aij. The AVE1 to AVEn are optional finite values.

When calculating the average value and standard deviation for measurement values obtained in this way after data conversion, the average values for the subsets Ai1 to Aim of set Ai were AVEi in all cases. More specifically, the average values for the subsets A11 to A1m of subset A1 were for example all AVE1. The standard deviations on the other hand became SD11 to SD1m and showed no difference in values either before or after data conversion. The same was also true for the other subsets A2 to An.

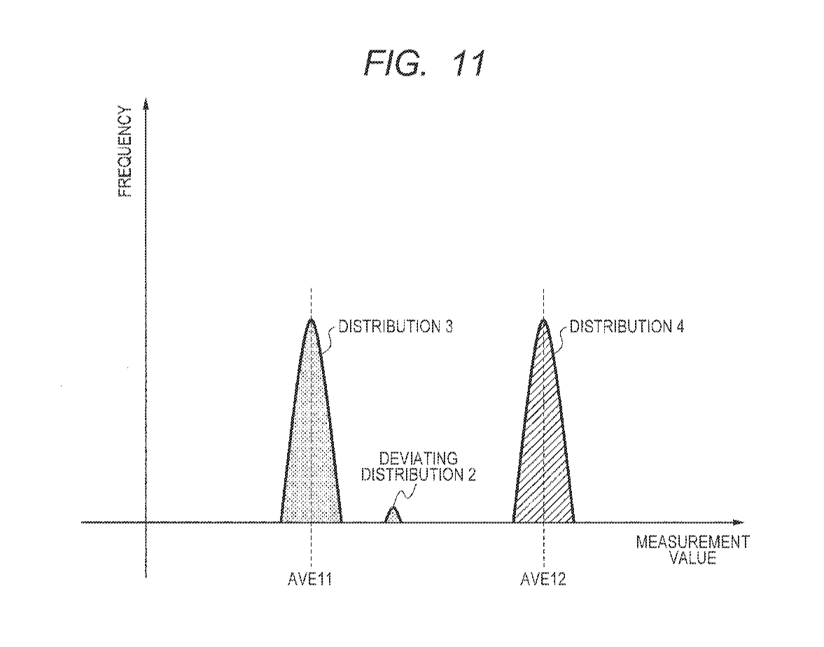

FIG. 11 is a drawing showing one example of a histogram of measurement values prior to data conversion. The histogram in FIG. 11 shows measurement values contained in the subsets A11 and A12. The measurement value distribution contained in the subset A11 is the distribution 3 and the deviating distribution 2, and distribution 3 is considered the main distribution. The measurement value distribution contained in the subset A12 is the distribution 4. The average value for the distribution configured from the distribution 3 and the deviating distribution 2 is AVE11, and the average value for the distribution 4 is AVE12.

In FIG. 11 there is a deviating distribution 2 whose measurement values deviate from the distribution 3. Here, if the distribution 3, the deviating distribution 2 and the distribution 4 are all considered as one distribution then a semiconductor device having measurement values corresponding to the deviating distribution 2 in FIG. 11 cannot be judged a defective item (semiconductor device possessing inherent latent defects). The reason is that deviating distributions are defined by the extent of separation from the distribution's average value, so that in this type of distribution the deviating distribution 2 cannot be defined as a deviating distribution.

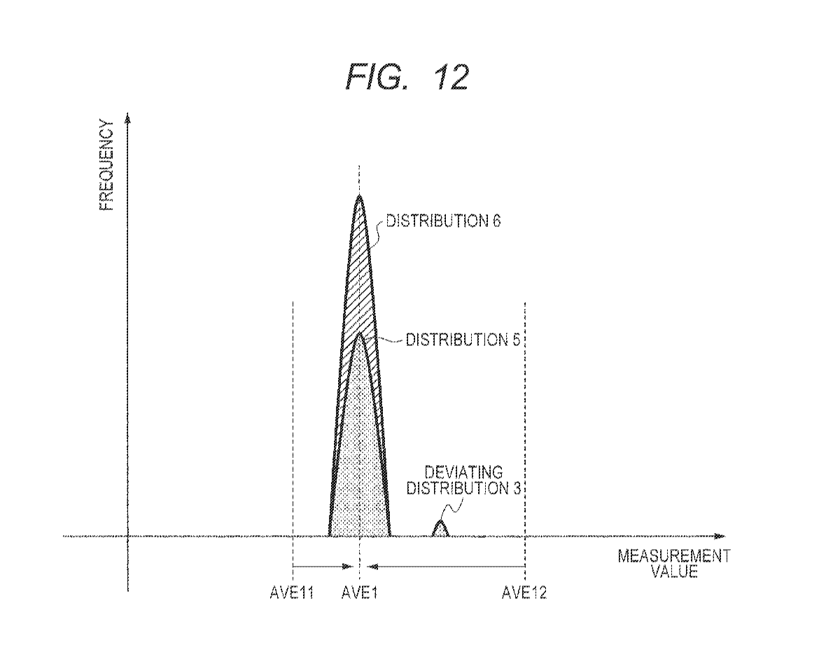

FIG. 12 is a drawing showing one example of a histogram of measurement values after data conversion. In FIG. 12, D11=AVE1 to AVE11 is added to each measurement value for the distribution 3 and deviating distribution 2, and D12=AVE to AVE12 is added to each measurement value in distribution 4 in FIG. 11. Consequently, the distribution 3 is converted to distribution 5, the distribution 4 to distribution 6, and the deviating distribution 2 is converted to deviating distribution 3. The average values for the distribution 5, deviating distribution 3, and distribution 6 are all AVE1 after conversion, and the distribution areas can be observed to mostly overlap each other. Namely, one could say the data conversion operation by the data converter 34 shifts each distribution in parallel along the X axis, converting to match the average values of the subset. Even if the distribution 5, deviating distribution 3 and distribution 6 in FIG. 12 are all considered as one distribution, in terms of the extent of separation from the distribution's average value that defines a deviating distribution, the deviating distribution 3 is protruding upwards so that a semiconductor device possessing measurement values corresponding to the deviating distribution 3 is identifiable by screening.

In step S106, the second average value and standard deviation calculator 35 finds the average value and standard deviation for the subset A1 to An after data conversion.

In step S107, the decision unit 36 utilizes the average value M and standard deviation SD and pre-established standard value information to screen (make a pass-fail decision) semiconductor devices whose measurement values correspond to those values contained in the subset A1 to An. Assume for example a lower limit value of a and an upper limit value of R. In this case, the semiconductor device is judged as possessing latent defect causes if the semiconductor device measurement values are lower than M+α×SD. Similarly, a semiconductor device having measurement values larger than M+β×SD is judged as possessing latent defect causes.

The screening device 1 of the present embodiment in this way, sub-groups the measurement values acquired from the plural wafers and plural measurement units into wafer subsets and measurement unit subsets. The screening device 1 converts data in the sub-grouped subsets so as to match average values of measurement values contained in each subset. The screening device 1 then calculates again the average values and standard deviations for the data-converted measurement values to identify semiconductor devices possessing latent defect causes.

Namely, an undetectable deviating distribution can be easily detected among plural distributions, by performing data conversion to add a fixed value to measurement values so that the average values of separated distributions mutually match each other.

Assuming that the distribution of measurement values are (widely) separated as shown in FIG. 11, then the overall distribution will expand to a large distribution and cause the deviating distribution 2 to sink low within the spread of the distribution range so that determining there are measurement values within the deviating distribution 2 that are outside the standard value range might prove impossible. However, the spread or widening of the overall distribution can be reduced by performing data conversion on measurement values to make the separate distributions match each other. This data conversion will allow easily detecting the deviating distribution without the deviating distribution sinking low into the (overall) spread of the distribution and permit screening out those semiconductor devices that possess latent defect causes.

### Second Embodiment

The second embodiment of the present invention is described next in detail while referring to the drawings.

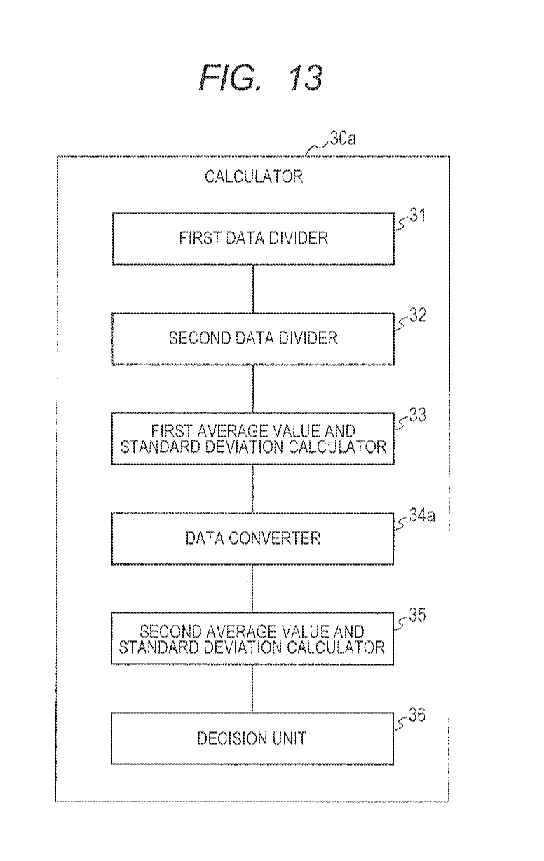

FIG. 13 is a diagram showing an example of the internal structure of the calculator 30a included in the screening device 2 of the second embodiment. In FIG. 13, the same structural elements as in FIG. 8 display the same reference numerals and their description is omitted. There are no differences in the overall structure of the screening devices 1 and 2 and so a description of the screening device 2 equivalent to that in FIG. 7 is omitted.

The point where the calculator 30 and the calculator 30a differs is that a data converter 34a is provided instead of a data converter 34.

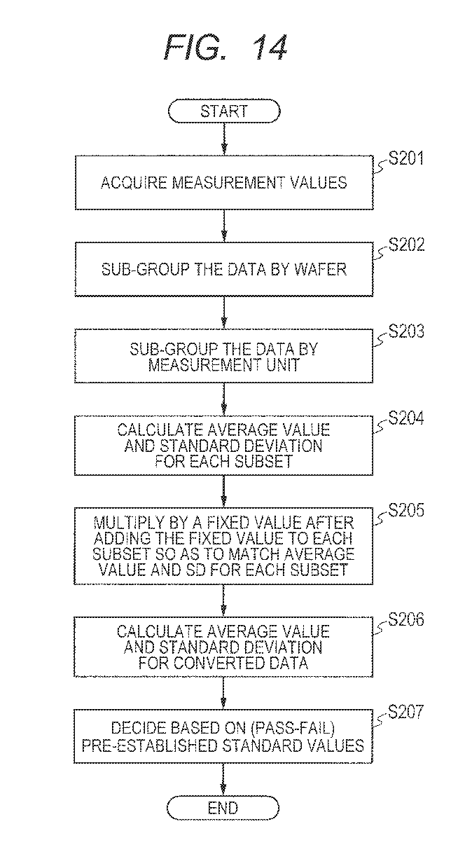

FIG. 14 is a flow chart showing an example of the operation of the screening device 2. The point where the flow chart in FIG. 9 differs from the flow chart in FIG. 14 is the process in step S105 and step S205. Therefore only the processing in step S205 is described.

In step S205, the data converter 34a performs conversion by adding a fixed value after multiplying each measurement value in each subset by a fixed value to match the average value and standard deviation of each subset.

Plural fixed values F11 to Fnm such as set in the following formula (2) are first of all established for the standard deviations SD11 to SDnm.

F11×SD11=F12×SD12=. . . =F1m×SD1m=SD1F21×SD21=F22×SD22=. . . =F2m×SD2m=SD2·Fn1×SDn1=Fn2×SDn2=. . . =Fnm×SDnm=SDn (2)

Here, SD1 to SDnm are optional finite values.

Next, fixed values G11 to Gnm such as set in the following formula (3) are established for the average values AVE11 to AVEnm.

F11×AVE11+G11=F12×AVE12+G12=. . . =F1m×AVE1m+G1m=AVE1F21×AVE21+G21=F22×AVE22+G22=. . . =F2m×AVE2m+G2m=AVE2·Fn1×AVEn1+Gn1=Fn2×AVEn2+Gn2=. . . =Fnm×AVEnm+Gnm=AVEn (3).

AVE1 to AVEn are optional finite values.

Next, conversion is performed by multiplying a fixed value Fij by a measurement value p contained in each element of the subset Aij, and adding a fixed value Gij to the measurement value after multiplication. The conversion then renders the following formula (4).

p×Fij+Gij (4)

In these type of converted measurement values, calculating an average value and standard deviation for each of the subsets A1 to An respectively yields the average values AVE1 to AVEn, and the standard deviations SD1 to SDn. The average values and standard deviation for each subset Aij of each subset Ai are respectively equivalent.

The processing described in the first and second embodiments may also be implemented by way of a screening program for semiconductor devices on a computer. Moreover, a computer and server can be coupled by way of a network, and a screening program for semiconductor devices stored on a storage medium coupled to the server. A computer connected over a network may execute the semiconductor device screening program stored on the storage medium to perform screening of the semiconductor devices.

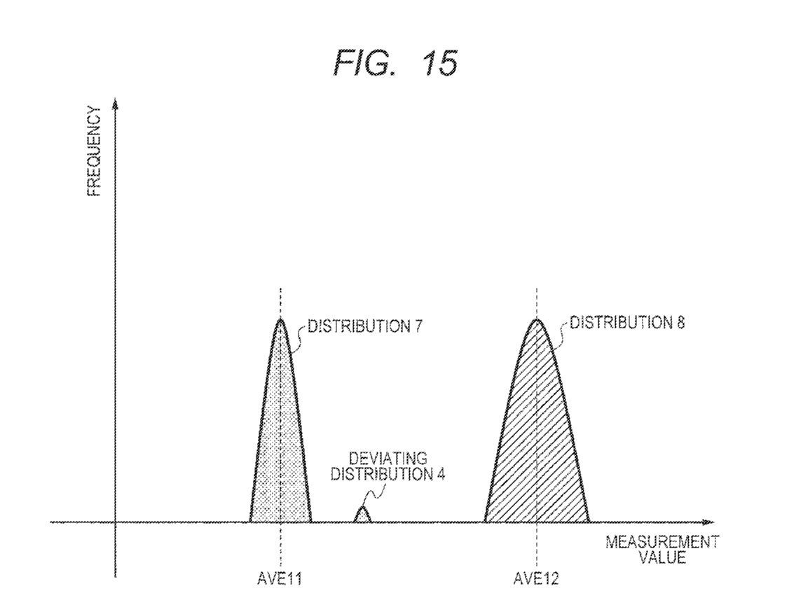

FIG. 15 is a drawing showing an example of a histogram for measurement values prior to data conversion. In the histogram shown in FIG. 15 not only are the measurement value distributions separated but the width between each distribution is also different. So detecting the deviating distribution 4 in distribution 7 is even more difficult.

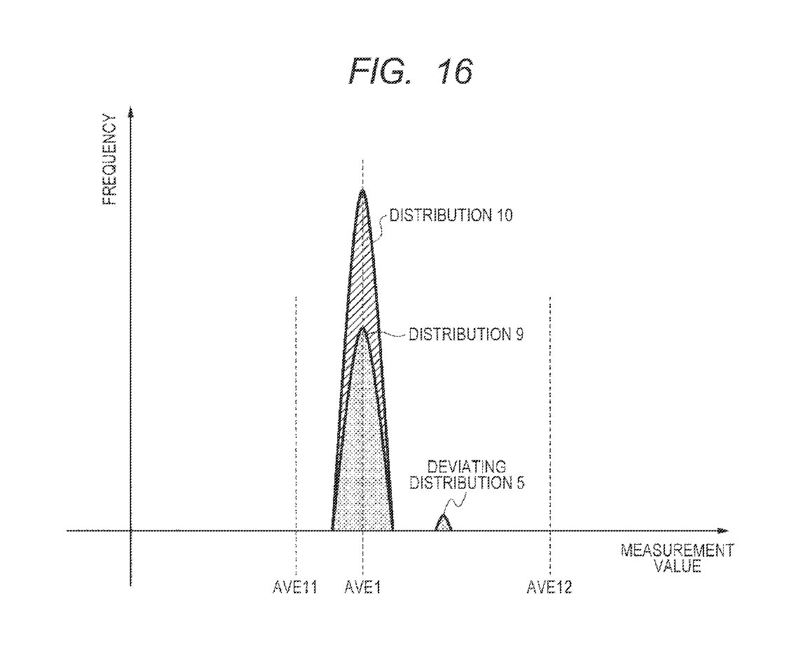

FIG. 16 is a drawing showing an example of a histogram for measurement values after data conversion. The distribution for measurement values shown in FIG. 16 match the average values of distribution 9 and distribution 10, and moreover also match the standard deviations in distribution 9 and distribution 10. The distribution 9 and distribution 10 are in other words converted so as to possess the same extent of distribution width. Detecting the deviating distribution 5 is therefore easy.

The screening device 2 of the present embodiment in this way not only matches up the average values in each subset but also performs data conversion of measurement values in each subset so as to equalize each distribution spread (width). Consequently even in cases where the spread or widening of each subset is non-uniform, the screening device can easily detect a deviating distribution that deviates from the main distribution.

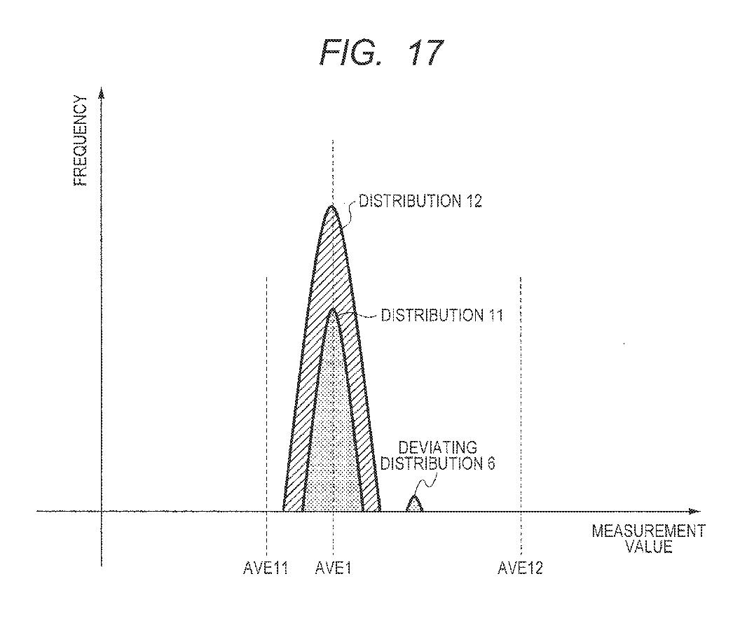

FIG. 17 is a drawing showing an example of a measurement value histogram. As can be seen in FIG. 17, even if the average values for the distribution 11 and distribution 12 after data conversion match each other, specifying the deviating distribution from each of those distributions is impossible in cases where the spread or widening is different between distributions. Judging whether or not a measurement value is within the deviating distribution depends on the spread or widening of each distribution. Therefore, simply adding a correction value to each measurement value as shown in FIG. 17 to overlay distributions just by an operation to make the distribution average values match each other will not correct the spread or widening among the distributions. This situation leads to the concern that identifying the deviating distribution might prove impossible.

The uniform width between distributions however can be obtained by correcting each distribution's width. The result as shown in FIG. 16 is that along with matching average values for each distribution, the standard deviation values that show the widening or spread of the distribution are also a match. Matching the average values and standard deviations that serve as the evaluation standard for each subset allows screening those semiconductor devices possessing latent defect causes.

The cited patent documents disclosed here were repeatedly referred to in these specifications. Moreover, the embodiments or examples may be revised or adjusted based on those basic technical concepts within the scope of the full disclosure (including the range of the specifications) of the present invention. Moreover, various types of disclosure elements (including each element of the claim items, each element of the embodiments, each element of the drawings, etc.) within the scope of the range of the claims of the present invention can be selected or utilized in a variety of combinations. In other words, the present invention may of course include all manner of variations and modifications achievable by one skilled in the art that conform to the technological concepts and full disclosure including the claims.

What is claimed is:

1. A screening device for semiconductor devices comprising:
a data divider configured to generate a plurality of measurement value subsets by sub-grouping a measurement value set including measurement results relating to characteristics of semiconductor device based on a specific standard;
a first evaluation value calculator configured to calculate a first evaluation value serving as an evaluation standard for measurement results contained in the respective measurement value subsets;
a data converter configured to convert measurement results contained in the respective measurement value subsets based on the first evaluation value;
a second evaluation value calculator configured to calculate a second evaluation value serving as an evaluation standard for measurement results after conversion by the data converter; and
a decision unit configured to decide if the semiconductor device under measurement is a pass or fail item based on the second evaluation value.

2. The screening device for semiconductor devices according to claim 1,
wherein the data divider includes:
a first data divider configured to sub-group the measurement value sets by each wafer containing the semiconductor device for measurement; and
a second data divider configured to sub-group the measurement value subsets sub-grouped by the first data divider.

3. The screening device for semiconductor devices according to claim 1,
wherein the first evaluation value calculator calculates an average value for the measurement results contained in the respective measurement subsets as a first evaluation value.

4. The screening device for semiconductor devices according to claim 3,
wherein the data converter calculates a first conversion coefficient for each of the plural measurement value subsets to match the respective average values calculated by the first evaluation value calculator, to serve as a conversion coefficient to add to the average values calculated by the first evaluation value calculator, and
performs a first conversion to add a first conversion coefficient to the measurement results contained in each of the measurement subsets.

5. The screening device for semiconductor devices according to claim 4,
wherein the first evaluation value calculator further calculates a standard deviation for measurement results contained in the respective measurement value subsets as a first evaluation value; and
wherein the data converter calculates a second conversion coefficient for each of the measurement value subsets to match the respective standard deviations calculated by the first evaluation value calculator to serve as a conversion coefficient to multiply by the standard deviation calculated by the first evaluation value calculator, and
performs a second conversion by multiplying the second conversion coefficient by the measurement results after the first conversion.

6. The screening device for semiconductor devices according to claim 1,
wherein the second evaluation value calculator calculates an average value and standard deviation for measurement results contained in each of the measurement value subsets after conversion by the data converter to serve as a second evaluation value.

7. The screening device for semiconductor devices according to claim 6,
wherein the decision unit judges the semiconductor device under measurement as a pass or a fail item based on the average value and standard deviation calculated by the second evaluation value calculator, and by pre-established standard value information.

8. A screening method for semiconductor devices comprising:
(a) dividing the data by generating a plurality of measurement values subsets by sub-grouping the measurement value sets including measurement results relating to characteristics of the semiconductor device based on a specific standard;
(b) calculating a first evaluation value serving as an evaluation standard for measurement results included in the respective measurement value subsets;
(c) converting the data by converting measurement results contained in the respective measurement value subsets based on the first evaluation value;
(d) calculating a second evaluation value that serves as an evaluation standard for measurement results after the data was converted; and
(e) deciding whether to pass or fail the semiconductor device under measurement based on the second evaluation value.

9. The screening method for semiconductor devices according to claim 8,
wherein the step (b) includes:
calculating an average value for measurement results contained in the respective measurement value subsets as a first evaluation value,
wherein the step (c) includes:
calculating a first conversion coefficient for each of the measurement value subsets to match the respective average values calculated in the first evaluation value calculation step, to serve as a conversion coefficient added to the average value calculated in the first evaluation calculation step; and
performing a first conversion to add the first conversion coefficient to the measurement results contained in the respective measurement value subsets.

10. The screening method for semiconductor devices according to claim 9,
wherein the step (b) further includes:
calculating a standard deviation for measurement results contained in the respective measurement value subsets as a first evaluation value; and
wherein the step (c) further includes:
calculating a second conversion coefficient for each of the measurement value subsets to match the respective standard deviations calculated in the step (b), to serve as a conversion coefficient multiplied by the standard deviation calculated in the step (b); and
performing a second conversion to multiply the measurement results after performing the first conversion, by the second conversion coefficient.

11. A computer readable medium storing a program to operate a computer as a screening device for semiconductor devices to execute a process comprising:
(a′) generating a plurality of measurement value subsets by sub-grouping a measurement value set including measurement results relating to characteristics of semiconductor device based on a specific standard;
(b′) calculating a first evaluation value serving as an evaluation standard for measurement results contained in the respective measurement value subsets;
(c′) converting measurement results contained in the respective measurement value subsets based on the first evaluation value;
(d′) calculating a second evaluation value serving as an evaluation standard for measurement results after conversion by (c′); and
(e′) deciding whether to pass or fail the semiconductor device under measurement based on the second evaluation value.

12. The computer readable medium storing the program according to claim 11,
wherein (b′) includes:
calculating an average value for measurement results contained in the respective measurement value subsets as a first evaluation value; and
wherein (c′) includes:
calculating a first conversion coefficient for each of the measurement value subsets to match the respective average values calculated in (b′), to serve as a conversion coefficient added to an average value calculated in (b′); and
performing a first conversion process to add the first conversion coefficient to the measurement results contained in the respective measurement value subsets.

13. The computer readable medium storing the program according to claim 12,
wherein (b′) further includes:
calculating a standard deviation for measurement results contained in the respective measurement value subsets as a first evaluation value, and
wherein the (c′) further includes:
calculating a second conversion coefficient for each of the measurement value subsets to match the respective standard deviations calculated in (b′) to serve as a conversion coefficient to multiply by the standard deviation calculated in (b′); and
performing a second conversion process to multiply the measurement results after performing the first conversion, by the second conversion coefficient.
